(19) United States
(12) Patent Application Publication
(10) Pub. No.: US 2026/0191044 A1
(43) Pub. Date: Jul. 2, 2026

(54) WAFER SCALE SYSTEM-IN-PACKAGE STRUCTURE AND METHOD FOR FORMING THE SAME

(71) Applicant: JCET Microelectronics (Jiangyin) Co., LTD., Jiangyin (CN)

(72) Inventors: Danfeng YANG, Jiangyin (CN); Songhua XU, Jiangyin (CN); Pingping LI, Jiangyin (CN); Qiang ZHAO, Jiangyin (CN); Fan YANG, Jiangyin (CN); Gu CAI, Jiangyin (CN); Tao HUANG, Jiangyin (CN); Yaojian LIN, Jiangyin (CN)

(73) Assignee: JCET Microelectronics (Jiangyin) Co., LTD., Jiangyin (CN)

(21) Appl. No.: 19/412,484

(22) Filed: Dec. 8, 2025

(30) Foreign Application Priority Data
Dec. 27, 2024 (CN) 202411950846.1

(51) Int. Cl. H10W 70/60; H10W 40/22; H10W 74/10; H10W 90/10

(52) U.S. Cl. CPC H10W 70/616; H10W 40/22; H10W 74/114; H10W 90/10

(57) ABSTRACT

A wafer scale system-in-package structure and a method for forming the same, are provided. The package structure includes: a silicon substrate comprising an upper surface and a lower surface opposite to the upper surface; functional submodules mounted on the upper surface of the silicon substrate and arranged in an array, wherein each of the functional submodules comprises four corners and four edges each between adjacent corners, and the functional submodules are electrically connected to the silicon substrate; a first bridge structure mounted on the upper surface of the silicon substrate at the edges of the functional submodules; a second bridge structure mounted on the upper surface of the silicon substrate at the corners of the functional submodules; and a first molding layer located on the upper surface of the silicon substrate and covering the functional submodules.

### CROSS-REFERENCE TO RELATED APPLICATIONS

This application claims the benefit of priority to Chinese Application No. 202411950846.1, filed on Dec. 27, 2024, which is incorporated herein by reference in its entirety.

### TECHNICAL FIELD

The present disclosure relates to the field of semiconductor package, and particularly relates to a wafer scale system-in-package structure and a method for forming the same.

### BACKGROUND

System in Package (SiP) is a technology that integrates chips with various different functions such as optoelectronics, digital/logic, radio frequency, memory, and etc., into a single package in the form of chip stack or package stack, thereby realizing a system that can achieve the above various functions.

The demand for data computation in today's emerging fields (mobile devices, artificial intelligence, automotive electronics, data storage, and etc.) is growing exponentially; in order to meet the requirements of high-performance computing such as high density, high speed, high heat dissipation, low power consumption, low latency and etc., existing system-in-package is expanding towards wafer scale, i.e., a plurality of chip submodules arranged in rows and columns are integrated on one silicon wafer to form a wafer scale system-in-package structure.

### SUMMARY

The present disclosure provides a wafer scale system-in-package structure and a method for forming the same.

The present disclosure first provides a wafer scale system-in-package structure, which includes: a silicon substrate, the silicon substrate including opposed upper surface and lower surface; a plurality of functional submodules mounted on the upper surface of the silicon substrate and arranged in an array, each function submodule including four corner heads and edges between adjacent corner heads, the function submodules being electrically connected with the silicon substrate; a first bridge structure mounted on the upper surface of the silicon substrate at the edges of the functional submodules, and the first bridge structure is used to interconnect adjacent functional submodules; a second bridge structure mounted on the upper surface of the silicon substrate at the corner heads of the functional submodules, and the second bridge structure is used to interconnect adjacent functional submodules around the corner heads; and a first molding layer located on the upper surface of the silicon substrate and covering the functional submodules, the first bridge structure, and the second bridge structure, and the first molding layer exposes the upper surfaces of the functional submodules, the first bridge structure, and the second bridge structure.

In some implementations, the structure of each functional submodule is the same, and the functional submodules include at least two semiconductor chips, and the at least two semiconductor chips are mounted on the upper surface of the silicon substrate in a flip-chip manner; each functional submodule further includes an underfill layer filled between the lower surface of the semiconductor chip in each functional submodule and the upper surface of the silicon substrate and covering the side surface of the semiconductor chip.

In some implementations, it further includes: edge dummy devices of different sizes mounted on the upper surface of the edge area of the silicon substrate outside the functional submodules array, and the first molding layer further covers the edge dummy devices and exposes the upper surfaces of the edge dummy devices; and the edge dummy devices are one or more of a passive device, a heat dissipation discrete component, or a dummy chip.

In some implementations, the first bridge structure includes a first line layer and a first support layer located on the upper surface of the first line layer, and the first line layer includes a first dielectric layer, first lines located in the first dielectric layer, and first welding bumps protruding from the lower surface of the first dielectric layer and electrically connected with the first lines, and when the first bridge structure is mounted on the upper surface of the silicon substrate, the first welding bumps are electrically connected with the silicon substrate, and the first bridge structure together with the silicon substrate interconnects adjacent functional submodules.

In some implementations, the first support layer of the first bridge structure is a single layer or a multi-layer stacked structure.

In some implementations, the material of the first support layer of the first bridge structure is one or more of silicon, germanium silicon, silicon carbide, glass, resin, or PCB core board.

In some implementations, the number of the first bridge structures mounted on the upper surface of the silicon substrate at each edge of the functional submodules is at least two, and the at least two first bridge structures are arranged in a direction parallel to the edge of the functional submodules.

In some implementations, the second bridge structure includes a second line layer and a second support layer located on the upper surface of the second line layer, and the second line layer includes a second dielectric layer, second lines located in the second dielectric layer, and second welding bumps protruding from the lower surface of the second dielectric layer and electrically connected with the second lines, and when the second bridge structure is mounted on the upper surface of the silicon substrate, the second welding bumps are electrically connected with the silicon substrate, and the second bridge structure together with the silicon substrate interconnects the adjacent functional submodules around the corner head.

In some implementations, the second support layer is a flexible structure, and the rigidity of the second support layer is less than the rigidity of the first molding layer.

In some implementations, the second support layer of the flexible structure includes a first buffer layer, a core layer located on the upper surface of the first buffer layer, and a second buffer layer located on the upper surface of the core layer, and the second buffer layer and the core layer have in them blind vias running through the second buffer layer and the core layer, and the first molding layer exposes the blind vias; and the sidewall surfaces of the blind vias further have a metal layer.

In some implementations, it further includes: a heat dissipation cover, the heat dissipation cover includes a horizontal cover top, a cover rim protruding from the lower surface of the edge of the horizontal cover top, and a plurality of downward anchoring protrusions protruding from the lower surface of the horizontal cover top, and the lower surface of the horizontal cover top of the heat dissipation cover is mounted on the upper surfaces of the first molding layer, the functional submodules, the first bridge structure, and the second bridge structure, and the anchoring protrusions are mounted in corresponding blind vias through adhesive, and the inner wall surface of the cover rim of the heat dissipation cover is mounted on the outer surface of the first molding layer and the silicon substrate.

In some implementations, the second support layer of the flexible structure includes a first buffer layer, a core layer located on the upper surface of the first buffer layer, and a second buffer layer located on the upper surface of the core layer, and the core layer has in it blind vias, and there are cavities in the blind vias, or filler material fully fills the blind vias, and the second buffer layer seals the openings of the blind vias, and the first molding layer exposes the upper surface of the second buffer layer; and the sidewall surfaces of the blind vias further have a metal layer.

In some implementations, it further includes: a heat dissipation cover, and the heat dissipation cover includes a horizontal cover top and a cover rim protruding from the lower surface of the edge of the horizontal cover top, and the lower surface of the horizontal cover top of the heat dissipation cover is mounted on the upper surface of the first molding layer, the functional submodules, the first bridge structure, and the second buffer layer of the second bridge structure, and the inner wall surface of the cover rim of the heat dissipation cover is mounted on the outer surface of the first molding layer and the silicon substrate.

In some implementations, the silicon substrate includes a silicon wafer body, a first redistribution layer located on the upper surface of the silicon wafer body, and a second redistribution layer located on the lower surface of the silicon wafer body, and the silicon wafer body has in it through-silicon-vias, the through-silicon-vias electrically connect the first redistribution layer and the second redistribution layer.

In some implementations, the functional submodules, the first bridge structure, and the second bridge structure are electrically connected with different parts of the first redistribution layer, respectively, and the adjacent functional submodules are interconnected through the first bridge structure and/or the second bridge structure and through a part of the first redistribution layer in the silicon substrate.

In some implementations, it further includes: a bridge chip mounted on the lower surface of the silicon substrate, and the bridge chip is electrically connected with a part of the second redistribution layer, and the bridge chip interconnects the adjacent functional submodules above the bridge chip through a part of the second redistribution layer, the through-silicon-vias, and a part of the first redistribution layer.

In some implementations, it further includes: metal bumps protruding from the lower surface of the silicon substrate and connected with a part of the second redistribution layer, and the lower surfaces of the metal bumps are not lower than the lower surface of the bridge chip; edge dummy devices of different sizes mounted on the lower surface of the edge area of the silicon substrate outside the functional submodules array; and a second molding layer located on the lower surface of the silicon substrate and covering the bridge chip, the metal bumps, and the edge dummy devices, and the second molding layer exposes the lower surfaces of the bridge chip, the metal bumps, and the edge dummy devices.

In some implementations, it further includes: a power supply module mounted on the lower surface of the second molding layer and electrically connected with the metal bumps, and the power supply module is used to supply power to at least two adjacent functional submodules on the upper surface of the silicon substrate.

In some implementations, it further includes: a bonding material that secures the four corner heads of the power supply module with the corresponding lower surfaces of the second molding layer.

In some implementations, it further includes: metal bumps protruding from the lower surface of the silicon substrate and connected with a part of the second redistribution layer, and the lower surfaces of the metal bumps are not lower than the lower surface of the bridge chip; a power supply module mounted on the lower surface of the metal bumps; edge dummy devices of different sizes mounted on the lower surface of the edge area of the silicon substrate outside the functional submodules array; and a second molding layer located on the lower surface of the silicon substrate and covering the bridge chip, the metal bumps, the power supply module, and the edge dummy devices, and the second molding layer exposes the lower surfaces of the power supply module and the edge dummy devices.

In some implementations, the structure of each functional submodule is the same, and the functional submodules include at least two semiconductor chips, and the at least two semiconductor chips are mounted on the upper surface of the silicon substrate in a flip-chip manner; each functional submodule further includes an underfill layer filled between the lower surface of the semiconductor chip in each functional submodule and the upper surface of the silicon substrate, and covering the side surface of the semiconductor chip.

The present disclosure further provides a method for forming a wafer scale system-in-package structure, which includes: providing a silicon substrate, the silicon substrate including opposed upper surface and lower surface; mounting, on the upper surface of the silicon substrate, a plurality of function submodules arranged in an array, and each function submodule includes four corner heads and edges located between adjacent corner heads, the function submodules being electrically connected with the silicon substrate; mounting a first bridge structure on the upper surface of the silicon substrate at the edges of the functional submodules, and the first bridge structure is used to interconnect adjacent functional submodules; mounting a second bridge structure on the upper surface of the silicon substrate at the corner heads of the functional submodules, and the second bridge structure is used to interconnect adjacent functional submodules around the corner heads; and forming, on the upper surface of the silicon substrate, a first molding layer covering the functional submodules, the first bridge structure, and the second bridge structure, and the first molding layer exposes the upper surfaces of the functional submodules, the first bridge structure, and the second bridge structure.

In some implementations, edge dummy devices of different sizes are mounted on the upper surface of the edge area of the silicon substrate outside the functional submodules array, and the first molding layer further covers the edge dummy devices and exposes the upper surfaces of the edge dummy devices; and the edge dummy devices are one or more of a passive device, a heat dissipation discrete component, or a dummy chip.

In some implementations, the first bridge structure includes a first line layer and a first support layer located on the upper surface of the first line layer, and the first line layer includes a first dielectric layer, first lines located in the first dielectric layer, and first welding bumps protruding from the lower surface of the first dielectric layer and electrically connected with the first lines, and the first welding bumps are electrically connected with the silicon substrate.

In some implementations, the second bridge structure includes a second line layer and a second support layer located on the upper surface of the second line layer, and the second line layer includes a second dielectric layer, second lines located in the second dielectric layer, and second welding bumps protruding from the lower surface of the second dielectric layer and electrically connected with the second lines, and the second welding bumps are electrically connected with the silicon substrate.

In some implementations, the second support layer is a flexible structure, and the rigidity of the second support layer is less than the rigidity of the first molding layer.

In some implementations, the second support layer of the flexible structure includes a first buffer layer, a core layer located on the upper surface of the first buffer layer, and a second buffer layer located on the upper surface of the core layer, and the second buffer layer and the core layer have in them blind vias running through the second buffer layer and the core layer, and the first molding layer exposes the blind vias; and it further includes: a heat dissipation cover, the heat dissipation cover includes a horizontal cover top, a cover rim protruding from the lower surface of the edge of the horizontal cover top, and a plurality of downward anchoring protrusions protruding from the lower surface of the horizontal cover top, and the lower surface of the horizontal cover top of the heat dissipation cover is mounted on the upper surfaces of the first molding layer, the functional submodules, and the first bridge structure, and the anchoring protrusions are mounted in corresponding blind vias through adhesive, and the inner wall surface of the cover rim of the heat dissipation cover is mounted on the outer surface of the first molding layer and the silicon substrate.

In some implementations, the second support layer of the flexible structure includes a first buffer layer, a core layer located on the upper surface of the first buffer layer, and a second buffer layer located on the upper surface of the core layer, and the core layer has in it blind vias, and there are cavities in the blind vias, or filler material fully fills the blind vias, and the second buffer layer seals the openings of the blind vias, and the first molding layer exposes the upper surface of the second buffer layer; and the sidewall surfaces of the blind vias further have a metal layer; and it further includes: mounting a heat dissipation cover, and the heat dissipation cover includes a horizontal cover top and a cover rim protruding from the lower surface of the edge of the horizontal cover top, and the lower surface of the horizontal cover top of the heat dissipation cover is mounted on the upper surface of the first molding layer, the functional submodules, the first bridge structure, and the second buffer layer of the second bridge structure, and the inner wall surface of the cover rim of the heat dissipation cover is mounted on the outer surface of the first molding layer and the silicon substrate.

In some implementations, the silicon substrate includes a silicon wafer body, a first redistribution layer located on the upper surface of the silicon wafer body, and a second redistribution layer located on the lower surface of the silicon wafer body, and the silicon wafer body has in it through-silicon-vias, the through-silicon-vias electrically connect the first redistribution layer and the second redistribution layer; the functional submodules, the first bridge structure, and the second bridge structure are electrically connected with different parts of the first redistribution layer, respectively, and the adjacent functional submodules are interconnected through the first bridge structure and/or the second bridge structure and through a part of the first redistribution layer in the silicon substrate.

In some implementations, it further includes: mounting a bridge chip on the lower surface of the silicon substrate, and the bridge chip is electrically connected with a part of the second redistribution layer, and the bridge chip interconnects the adjacent functional submodules above the bridge chip through a part of the second redistribution layer, the through-silicon-vias, and a part of the first wiring layer.

In some implementations, it further includes: forming, on the lower surface of the silicon substrate, metal bumps protruding and connected with a part of the second redistribution layer, and the lower surfaces of the metal bumps are not lower than the lower surface of the bridge chip; mounting edge dummy devices of different sizes on the lower surface of the edge area of the silicon substrate outside the functional submodules array; forming, on the lower surface of the silicon substrate, a second molding layer covering the bridge chip, the edge dummy devices, and the metal bumps, and the second molding layer exposes the lower surfaces of the bridge chip, the metal bumps, and the edge dummy devices; mounting, on the lower surface of the second molding layer, a power supply module electrically connected with the metal bumps, and the power supply module is used to supply power to at least two adjacent functional submodules on the upper surface of the silicon substrate.

In some implementations, a bonding material is formed that secures the four corner heads of the power supply module with the corresponding lower surfaces of the second molding layer.

In some implementations, metal bumps protruding and connected with a part of the second redistribution layer are formed on the lower surface of the silicon substrate, and the lower surfaces of the metal bumps are not lower than the lower surface of the bridge chip; a power supply module is mounted on the lower surface of the metal bumps; edge dummy devices of different sizes are mounted on the lower surface of the edge area of the silicon substrate outside the functional submodules array; and a second molding layer covering the bridge chip, the metal bumps, the power supply module, and the edge dummy devices is formed on the lower surface of the silicon substrate, and the second molding layer exposes the lower surfaces of the power supply module and the edge dummy devices.

### BRIEF DESCRIPTION OF THE DRAWINGS

FIG. 1 is a top-view structural schematic diagram of a wafer scale system-in-package structure in one embodiment of the present disclosure;

FIG. 2 is a cross-sectional structural schematic diagram along the direction of the cutting line AA1 in FIG. 1;

FIG. 3 is a cross-sectional structural schematic diagram along the direction of the cutting line BB1 in FIG. 1;

FIG. 4 is a structural schematic diagram of a second bridge structure in one embodiment of the present disclosure;

FIG. 5 is a structural schematic diagram of a second bridge structure in yet another embodiment of the present disclosure;

FIG. 6 is a structural schematic diagram of a wafer scale system-in-package structure in another embodiment of the present disclosure;

FIG. 7 is a structural schematic diagram of the wafer scale system-in-package structure in yet another embodiment of the present disclosure;

FIG. 8 is a structural schematic diagram of the wafer scale system-in-package structure in yet another embodiment of the present disclosure;

FIG. 9 is a structural schematic diagram of the wafer scale system-in-package structure in yet another embodiment of the present disclosure;

FIG. 10 is a structural schematic diagram of a wafer scale system-in-package structure in yet another embodiment of the present disclosure; and

FIG. 11 is a structural schematic diagram of a wafer scale system-in-package structure in yet another embodiment of the present disclosure.

### DETAILED DESCRIPTION

The implementations of the present disclosure are described in detail below in conjunction with the accompanying drawings. For the sake of explanation, when describing the embodiments of the present disclosure in detail, the schematic diagram will not be enlarged to a general proportion; furthermore, the schematic diagram is merely an example, which should not limit the scope of protection of the present disclosure. Additionally, in actual production, the three-dimensional spatial dimensions of length, width, and depth should be included.

The band-width of existing wafer scale system-in-package structures still needs to be improved.

In the wafer scale system-in-package structure and the method for forming the same in the aforementioned embodiments of the present disclosure, in one embodiment, the package structure includes: a silicon substrate, the silicon substrate including opposed upper surface and lower surface; a plurality of functional submodules mounted on the upper surface of the silicon substrate and arranged in an array, each function submodule including four corner heads and edges between adjacent corner heads, the function submodules being electrically connected with the silicon substrate; a first bridge structure being mounted on the upper surface of the silicon substrate at the edges of the functional submodules, and the first bridge structure is used to interconnect adjacent functional submodules; a second bridge structure mounted on the upper surface of the silicon substrate at the corner heads of the functional submodules, and the second bridge structure is used to interconnect adjacent functional submodules around the corner heads; and a first molding layer located on the upper surface of the silicon substrate and covering the functional submodules, the first bridge structure, and the second bridge structure, and the first molding layer exposes the upper surfaces of the functional submodules, the first bridge structure, and the second bridge structure. In the present disclosure, since in addition to the fact that adjacent functional submodules can be interconnected through the silicon substrate (a part of the first redistribution layer in the silicon substrate), adjacent functional submodules can also be interconnected through the first bridge structure mounted on the upper surface of the silicon substrate at the edges of the functional submodules, thereby increasing channels for connection (or interconnection) between adjacent functional submodules, so as to improve the band-width between adjacent functional submodules, thus improving the overall band-width of the wafer scale system-in-package structure. Moreover, the second bridge structure includes a second line layer and a second support layer located on the upper surface of the second line layer, and the second line layer includes a second dielectric layer, second lines located in the second dielectric layer, and second welding bumps protruding from the lower surface of the second dielectric layer and electrically connected with the second lines, and when the second bridge structure is mounted on the upper surface of the silicon substrate, the second welding bumps are electrically connected with the silicon substrate, and the second bridge structure together with the silicon substrate interconnects the adjacent functional submodules around the corner head. Through the second bridge structure of the aforementioned specific structure, channels for connection of adjacent functional submodules are further increased through the second bridge structure (in addition to including wirings in the silicon substrate and the first bridge structure, it further includes the second bridge structure), thereby further improving the band-width between adjacent functional submodules, thus further improving the overall band-width of the wafer scale system-in-package structure, meanwhile, the large stresses existing at the corner heads and near the corner heads of adjacent functional submodules can be buffered and balanced through the second support layer, so that the warping in the wafer scale system-in-package structure caused by large stress at the corner heads of the functional submodules.

Furthermore, in one embodiment, a plurality of edge dummy devices of different sizes are mounted on the upper surface of the edge area, such that the amount of the first molding layer on the upper surface of the edge area of the silicon substrate is reduced, thereby improving the Si/EMC ratio of the edge area (the EMC is a molding material, and the edge dummy devices are equivalent to Si), and thus reducing the difference between the Si/EMC ratio of the edge area and the Si/EMC ratio of the central area, therefore, the warping problems in wafer scale system-in-package structures caused by the large difference in Si/EMC ratio between the edge area and the central area are prevented, thereby effectively controlling warping of system-in-package structures of wafer scale ultra large chip module at room temperature or high temperature.

Furthermore, in one embodiment, the first bridge structure includes a first line layer and a first support layer located on the upper surface of the first line layer, and the first line layer includes a first dielectric layer, first lines located in the first dielectric layer, and first welding bumps protruding from the lower surface of the first dielectric layer and electrically connected with the first lines, and when the first bridge structure is mounted on the upper surface of the silicon substrate, the first welding bumps are electrically connected with the silicon substrate, and the first bridge structure together with the silicon substrate interconnects adjacent functional submodules. The first bridge structure uses the aforementioned specific structure, and interconnection between adjacent functional submodules is achieved through the first line layer, thereby increasing channels of connection between adjacent functional submodules (in addition to including wirings in the silicon substrate, it further includes the first bridge structure), so as to improve the band-width between adjacent functional submodules, thus improving the overall band-width of the wafer scale system-in-package structure, meanwhile, the amount of the first molding layer formed on the upper surface of the silicon substrate can be reduced by the first support layer, thereby improving the Si/EMC ratio within the wafer scale system-in-package structure, thereby reducing the overall warping caused by the small Si/EMC ratio in the wafer scale system-in-package structure.

Furthermore, in one embodiment, the second support layer of the flexible structure includes a first buffer layer, a core layer located on the upper surface of the first buffer layer, and a second buffer layer located on the upper surface of the core layer, the second buffer layer and the core layer have in them blind vias running through the second buffer layer and the core layer; on the one hand, the rigidity of the second support layer of this structure is small, so that the larger stresses existing at the corner heads and near the corner heads of adjacent functional submodules are effectively buffered and balanced; on the other hand, when mounting the heat dissipation cover, the second support layer provides support and cushioning pads for the back surface of the heat dissipation cover, and provides a mounting interface for the anchoring protrusions of the lower surface of the cover top of the heat dissipation cover; meanwhile, when mounting the heat dissipation cover, the anchoring protrusions of the lower surface of the cover top of the heat dissipation cover are correspondingly mounted in the corresponding blind vias, i.e., the blind vias also provide a limiting space for the anchoring protrusions of the lower surface of the cover top of the heat dissipation cover, which improves the alignment accuracy when mounting the heat dissipation cover, and defines the mounting accuracy of the heat dissipation cover during the mounting process and the adhering process of the heat dissipation cover, and when the anchoring protrusions of the lower surface of the cover top of the heat dissipation cover are correspondingly mounted in the corresponding blind vias, the anchoring protrusions are locked in the blind vias, which improves the firmness of mounting of the heat dissipation cover.

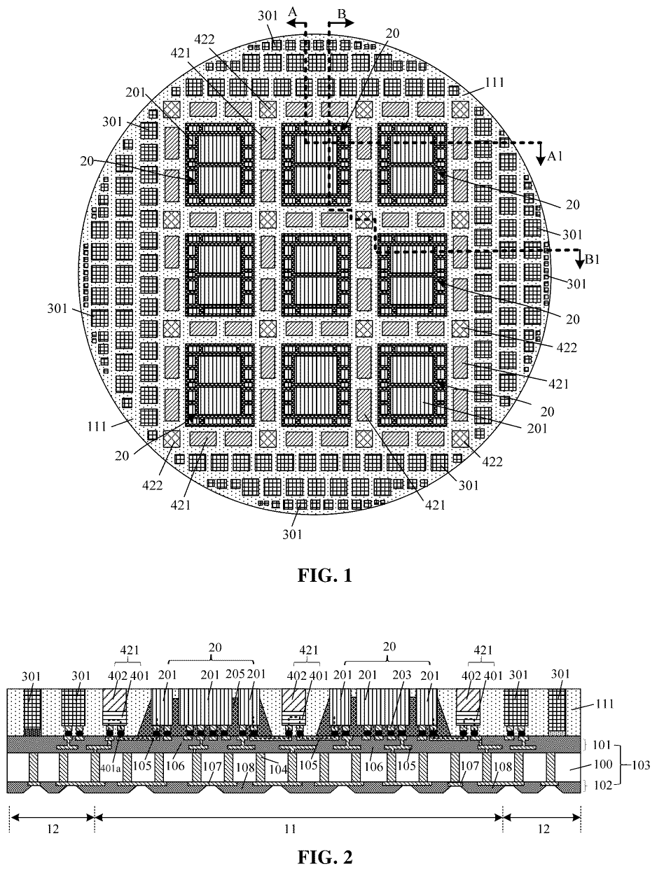

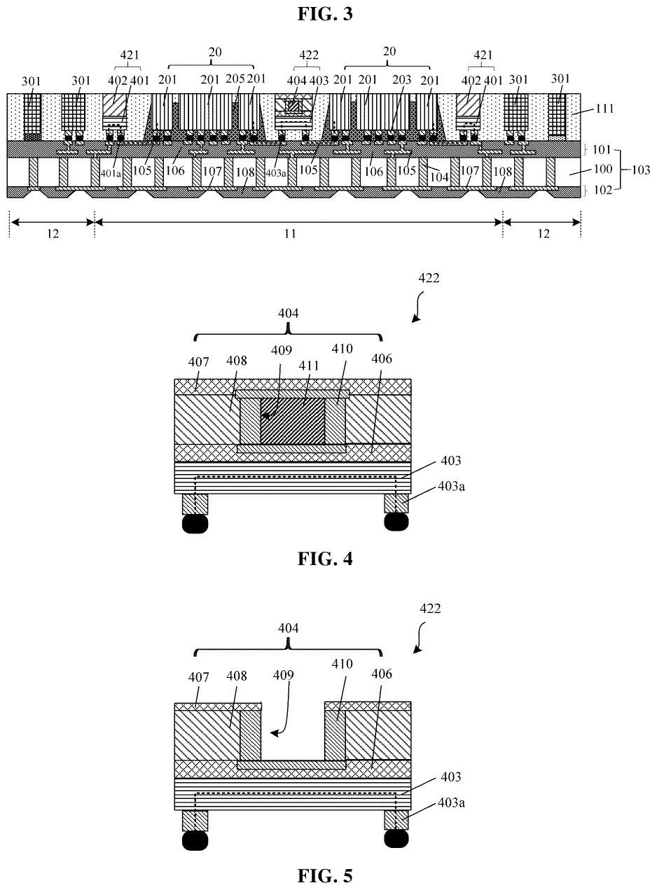

An embodiment of the present disclosure first provides a system-in-package structure, referring to FIGS. 1-3, wherein FIG. 2 is a cross-sectional structural schematic diagram along the direction of the cutting line AA1 in FIG. 1, FIG. 3 is a cross-sectional structural schematic diagram along the direction of the cutting line BB1 in FIG. 1, and it includes: a silicon substrate 103, the silicon substrate 103 including opposed upper surface and lower surface; a plurality of functional submodules 20 mounted on the upper surface of the silicon substrate 103 and arranged in an array, each function submodule 20 including four corner heads and edges between adjacent corner heads, the function submodules 20 being electrically connected with the silicon substrate 103; a first bridge structure 421 mounted on the upper surface of the silicon substrate 103 at the edges of the functional submodules 20, and the first bridge structure 421 is used to interconnect adjacent functional submodules 20; a second bridge structure 422 mounted on the upper surface of the silicon substrate 103 at the corner heads of the functional submodules 20, and the second bridge structure 422 is used to interconnect adjacent functional submodules 20 around the corner heads; and a first molding layer 111 located on the upper surface of the silicon substrate 103 and covering the functional submodules 20, the first bridge structure 421, and the second bridge structure 422, and the first molding layer 111 exposes the upper surfaces of the functional submodules 20, the first bridge structure 421, and the second bridge structure 422.

In some implementations, the silicon substrate 103 includes a silicon wafer body 100, a first redistribution layer 101 located on the upper surface of the silicon wafer body 100, and a second redistribution layer 102 located on the lower surface of the silicon wafer body 100.

The material of the silicon wafer body 100 is silicon, the silicon wafer body 100 may be circular or square, and correspondingly, the shape of the silicon substrate 103 is also circular or square. In the present embodiment, the package structure is a wafer scale system-in-package structure, and the dimension of the wafer scale system-in-package structure is large, and the dimensions of the corresponding silicon wafer body 100 and the silicon substrate 103 will also be large. In some implementations, when the silicon wafer body 100 and the silicon substrate 103 are circular, the diameter dimensions of the silicon wafer body 100 and the silicon substrate 103 may be 300 mm, 450±5 mm, when the silicon wafer body 100 and the silicon substrate 103 are square, the diagonal dimensions of the silicon wafer body 100 and the silicon substrate 103 may be 300 mm, 450±10 mm.

In one embodiment, the silicon wafer body 100 has in it through-silicon-vias 104 and a microdevice (not shown in the figures), the through-silicon-vias 104 are electrically connected with the first redistribution layer 101 and the second redistribution layer 102. In some implementations, the through-silicon-vias 104 are located in the silicon wafer body, and the through-silicon-vias 104 run through the upper surface and the lower surface of the silicon wafer body 100, the upper ends of the through-silicon-vias 104 are electrically connected with the first redistribution layer 101, and the lower ends of the through-silicon-vias 104 are electrically connected with the second redistribution layer 102, and the material of the through-silicon-vias 104 is metal, in some implementations, it may be one or more of Al, Cu, W, Au, Ag, Pt, Ni, Ti, Ta, TiN, TaN, TaC, or WN. The microdevice may be electrically connected with the first redistribution layer 101, the microdevice, in combination with the first redistribution layer 101 (and the second redistribution layer 102), may form a circuit with specific functions, the specific functions may be one or more of signal decoupling and voltage stabilization, anti-electrostatic and overvoltage protection, or signal filtering, and the specific functions may also include other suitable functions. The microdevice may be formed in the silicon wafer body 100 and/or on the upper surface of the silicon wafer body through semiconductor integrated manufacturing processes. In one embodiment, the microdevice is one or more of a Deep Trench Capacitor (DTC), a protective diode, and a ground inductor, the high-density trench capacitor may be used for decoupling and voltage stabilization, the protective diode may be used for anti-electrostatic and overvoltage protection, and the ground inductor may be used for signal filtering or isolation.

The first redistribution layer 101 is located on the upper surface of the silicon wafer body 100, the functional submodules 20, the first bridge structure 421, and the second bridge structure 422 are electrically connected with different parts of the first redistribution layer 101, respectively. The electrical connection of the functional submodules 20 with the silicon substrate 103 includes: the plurality of functional submodules 20 are electrically connected with a part of the first redistribution layer 101 in the silicon substrate 103, and it may further includes: adjacent functional submodules 20 are interconnected through a part of the first redistribution layer 101 in the silicon substrate 103.

In some implementations, the first redistribution layer 101 includes a first passivation layer 106 located on the upper surface of the silicon wafer body 100 and first wirings 105 located in the first passivation layer 106, and when the through-silicon-vias 104 are electrically connected with the first redistribution layer 101 and the functional submodules 20 are electrically connected with the first redistribution layer 101, both the through-silicon-vias 104 and the functional submodules 20 are electrically connected with the corresponding parts of the first wirings 105 in the first redistribution layer 101, and the electrical connection of the plurality of functional submodules 20 with the silicon substrate 103 includes: the plurality of functional submodules 20 are electrically connected with a part of the first wirings 105 in the first redistribution layer 101 in the silicon substrate 103, and adjacent functional submodules 20 are interconnected through a part of the first wirings 105 in the first redistribution layer 101 in the silicon substrate 103. In one embodiment, the first passivation layer 106 may be a single layer or a multi-layer stacked structure, and correspondingly, the first wirings 105 may also be a single-layer or a multi-layer line structure. The material of the first passivation layer 106 may be an inorganic material or an organic material, and the inorganic material may be one or more of silicon oxide, silicon nitride, silicon oxynitride, silicon oxycarbide, or silicon carbonitride, and the organic material may be a polymer resin material, in some implementations, it may include epoxy resin, polyimide resin, benzocyclobutene resin, or polybenzoxazole resin. The material of the first wirings 105 is a metal, in some implementations, it may be one or more of Al, Cu, W, Au, Ag, Pt, Ni, Ti, Ta, TiN, TaN, TaC, or WN. In some implementations, the first passivation layer 106 is a double-layer stacked structure, which includes an inorganic material passivation layer located on the upper surface of the silicon wafer body 100 and an organic material passivation layer located on the surface of the inorganic material passivation layer.

The second redistribution layer 102 is located on the lower surface of the silicon wafer body 100. In one embodiment, the second redistribution layer 102 includes a second passivation layer 108 located on the lower surface of the silicon wafer body 100 and second wirings 107 located in the second passivation layer 108, and when the through-silicon-vias 104 are electrically connected with the second redistribution layer 102, the through-silicon-vias 104 are electrically connected with the corresponding parts of the second wirings 107 in the second redistribution layer 102. In some implementations, the second passivation layer 108 may be a single layer or a multi-layer stacked structure, and correspondingly, the second wirings 107 may also be a single-layer or a multi-layer line structure. The material of the second passivation layer 108 may be an inorganic material or an organic material, and the inorganic material may be one or more of silicon oxide, silicon nitride, silicon oxynitride, silicon oxycarbide, or silicon carbonitride, and the organic material may be a polymer resin material, in some implementations, it may include epoxy resin, polyimide resin, benzocyclobutene resin, or polybenzoxazole resin. The material of the second wirings 107 is a metal, in some implementations, it may be one or more of Al, Cu, W, Au, Ag, Pt, Ni, Ti, Ta, TiN, TaN, TaC, or WN. In some implementations, the second passivation layer 108 is a double-layer stacked structure, which includes an inorganic material passivation layer located on the lower surface of the silicon wafer body 100 and an organic material passivation layer located on the surface of the inorganic material passivation layer.

In one embodiment, the silicon substrate 103 may include a central area 11 and an edge area 12 around the central area 11, and the plurality of functional submodules 20 and the first bridge structure 421 are both mounted on the upper surface of the central area 11.

Due to its small width, the functional submodules 20 cannot be mounted in the edge area 12 of the silicon substrate 103, and by research, it has been found that when the upper surface of edge area 12 is completely covered by the first molding layer 111, there is no silicon material on the upper surface of the edge area 12, and the Si/EMC ratio is small (Si is silicon and EMC is molding material), while the functional submodules are mounted on the upper surface of the central area 11, i.e., most of the central area is silicon material and a small part is the first molding layer material, and the Si/EMC ratio is large, and this will result in a significant difference in the Si/EMC ratio between the edge area 12 and the central area 11 of the silicon substrate 103, which will lead to warping of the substrate. Therefore, in one embodiment, a plurality of edge dummy devices 301 of different sizes may be mounted on the upper surface of the edge area 12. A plurality of edge dummy devices 301 of different sizes are mounted on the upper surface of the edge area 12 of the silicon substrate 103, such that the amount of the first molding layer 111 on the upper surface of the edge area 12 of the silicon substrate 103 is reduced, thereby raising the Si/EMC ratio of the edge area 12 (the EMC is a molding material, and the edge dummy devices 301 are equivalent to Si), and thus reducing the difference between the Si/EMC ratio of the edge area 12 and the Si/EMC ratio of the central area 11, therefore, the warping problems in wafer scale system-in-package structures caused by the large difference in Si/EMC ratio between the edge area 12 and the central area 11 are prevented, thereby effectively controlling warping of system-in-package structures of wafer scale ultra large chip module at room temperature or high temperature.

In one embodiment, the edge dummy devices 301 may include one or more of passive devices, heat dissipation discrete components, or dummy chips. In some implementations, when the edge dummy devices 301 mounted on the upper surface of the edge area of the silicon substrate 103 are passive devices, the passive devices may be electrically connected with the silicon substrate 103, and the passive devices may be one or more of resistors, capacitors, or inductors. In another specific embodiment, when the edge dummy devices 301 mounted on the upper surface of the edge area of the silicon substrate 103 are heat dissipation discrete components, such as heat dissipation metal blocks, the lower surface of the heat dissipation discrete components are adhered on the upper surface of the edge area 12 of the silicon substrate 103 through a heat dissipation adhesive, and the heat dissipation discrete components may be used for heat dissipation of the package structure, and the material of the heat dissipation discrete components is metal material used for heat dissipation. In another specific embodiment, when the edge dummy devices 301 mounted on the upper surface of the edge area of the silicon substrate 103 are dummy chips, the lower surface of the dummy chips are adhered on the upper surface of the edge area 12 of the silicon substrate 103 through an adhesive, and the dummy chips are silicon dies without lines.

In one embodiment, the dimensions of edge dummy devices 301 far away from the central area 11 are smaller than the dimensions of edge dummy devices 301 close to the central area 11. By fully mounting edge dummy devices 301 on the upper surface of the edge area 12, the material of the first molding layer 111 on the edge area 12 may be further reduced, thereby further improving the Si/EMC ratio of the edge area 12 of the silicon substrate 103, and thus further reducing the difference between the Si/EMC ratio of the edge area 12 and the Si/EMC ratio of the central area 11, which is conducive to better preventing warping of the silicon substrate 103.

In one embodiment, the edge dummy devices 301 mounted on a part of the upper surface of the edge area 12 close to the central area 11 are passive devices, and the edge dummy devices 301 mounted on a part of the upper surface far away from the central area 11 are heat dissipation discrete components or dummy chips, the mounting method of the passive devices (edge dummy devices 301) close to the central area 11 may be the same as the mounting method of the functional modules 20 to maintain consistency in mounting methods and reduce the generation of stress.

In one embodiment, when a plurality of edge dummy devices 301 are mounted on the upper surface of the edge area 12 of the silicon substrate 103, the edge dummy devices may be arranged in rows or columns.

The functional submodules 20 are chip modules with specific functions. A plurality of functional submodules 20 are mounted in an array arrangement on the upper surface of the silicon substrate 103. The number of functional submodules 20 is at least 2, in some implementations, it may be 2, 4, 9, 16, 25, or more (e.g., N², where N is greater than 5), a plurality of functional submodules 20 may be mounted in a 1×1, 2×2, 3×3, 4×4, 5×5 array arrangement, or in an array arrangement with more modules, on the upper surface of the silicon substrate 103. FIG. 1 illustrates an example where nine functional submodules 20 are mounted in a 3×3 array arrangement on the upper surface of the silicon substrate 103.

In one embodiment, each functional submodule 20 has the same structure and the same function, each functional submodule 20 may be cuboid or cube, and each functional submodule 20 includes four corner heads and edges between adjacent corner heads, i.e., it includes four corner heads and four edges. In other embodiments, the functional submodules 20 may be other shapes, such as cuboid-like, cube-like, parallelepiped, or other regular three-dimensional shapes. In one embodiment, each functional submodule 20 includes in it at least two (or more) semiconductor chips 201. In some implementations, when each functional submodule 20 includes in it at least two semiconductor chips 201, the dimensions and/or functions of the at least two semiconductor chips 201 are different. In another specific embodiment, when each functional submodule 20 includes in it at least two semiconductor chips 201, the dimensions and/or functions of a partial number of the semiconductor chips 201 may be the same, and the dimensions and/or functions of a partial number of the semiconductor chips 201 may be different. In one embodiment, the semiconductor chip 201 includes but is not limited to a signal processing chip, a logic control chip, a memory chip, a sensor chip, a power supply chip, or a radio frequency chip.

The functional submodules 20 being mounted on the upper surface of the silicon substrate 103 includes: the semiconductor chip 201 in each functional submodule 20 is mounted on the upper surface of the silicon substrate 103 in a flip-chip manner. In one embodiment, the semiconductor chip 201 includes opposed active surface and back surface, and the active surface has on it welding bumps 203, and an integrated circuit with specific functions (not shown in the figures) is formed in the semiconductor chip 201, and the welding bumps 203 are electrically connected with the integrated circuit. When the semiconductor chips 201 in the functional submodules 20 are mounted on the upper surface of the silicon substrate 103 in a flip-chip manner, the active surfaces of the semiconductor chips 201 face downward, and the welding bumps 203 on the active surfaces are welded together with corresponding first wirings 105 in the first redistribution layer 101 of the silicon substrate 103. In one embodiment, the welding bumps 203 may include solder pads and a solder layer located on the surface of the solder pads; in another embodiment, the welding bumps 203 may also include solder pads, a metal pillar located on the surface of the solder pads, and a solder layer on the top surface of the metal pillar. The material of the solder pads and metal pillar is metal, which may be one or more of aluminum, copper, nickel, tin, titanium, tungsten, platinum, chromium, tantalum, gold, or silver. The material of the solder layer is tin or tin alloy, the tin alloy is one or more of tin-silver, tin-zinc, tin-lead, tin-indium, tin-gold, tin-copper, tin-silver-copper, tin-silver-zinc, tin-bismuth-indium, tin-zinc-indium, or tin-silver-antimony.

In one embodiment, each functional submodule 20 further includes an underfill layer 205 filled between the lower surface (active surface) of the semiconductor chips 201 in each functional submodule 20 and the upper surface of the silicon substrate 103, and covering the side surfaces of the semiconductor chips 201. In one embodiment, the underfill layer 205 may cover part or all of the sidewalls of the semiconductor chips 201. In one embodiment, the underfill layer 205 on the sidewall surfaces of the semiconductor chips 201 has inclined sidewalls.

In the present disclosure, in addition to the fact that adjacent functional submodules 20 may be interconnected through the silicon substrate 103 (a part of the first redistribution layer 101 in the silicon substrate 103 (or a part of the first wirings 105)), adjacent functional submodules 20 can also be interconnected through the first bridge structure 421 mounted on the upper surface of the silicon substrate 103 at the edges of the functional submodules 20, thereby increasing channels for connection (or interconnection) between adjacent functional submodules 20 (also including the first bridge structure 421 in addition to the wirings in the silicon substrate 103), which improves the band-width between adjacent functional submodules 20, thus improving the overall band-width of the wafer scale system-in-package structure.

In one embodiment, the first bridge structure 421 interconnects two adjacent functional submodules 20 on two sides.

In one embodiment, referring to FIG. 2 or FIG. 3, the first bridge structure 421 includes a first line layer 401 and a first support layer 402 located on the upper surface of the first line layer 401, and the first line layer 401 includes a first dielectric layer, first lines located in the first dielectric layer (not shown in the figures), and first welding bumps 401a protruding from the lower surface of the first dielectric layer and electrically connected with the first lines, and when the first bridge structure 421 is mounted on the upper surface of the silicon substrate 103, the first welding bumps 401a are electrically connected with a part of the first redistribution layer 101 in the silicon substrate 103, and the first bridge structure 421 together with a part of the first redistribution layer 101 in the silicon substrate 103 interconnects adjacent functional submodules 20. The first bridge structure 421 uses the aforementioned specific structure, and interconnection between adjacent functional submodules 20 is achieved through the first line layer 401, thereby increasing channels of connection between adjacent functional submodules 20 (also including the first bridge structure 421 in addition to wirings in the silicon substrate 103), so as to improving the band-width between adjacent functional submodules 20, thus improving the overall band-width of the wafer scale system-in-package structure. Meanwhile, the first support layer 402 provides physical support for the first line layer 401 (because the thickness of the first line layer 401 is typically very thin and cannot be processed as a standalone device) and protects the first line layer 401 from failures such as breakage of lines caused by warping; moreover, the first support layer 402 can also reduce the amount of the first molding layer 111 formed on the upper surface of the silicon substrate 103, thereby increasing the Si/EMC ratio within the wafer scale system-in-package structure (the first support layer 402 is equivalent to Si), thus reducing the overall warping caused by the low Si/EMC ratio in the wafer scale system-in-package structure. In other embodiments, the first bridge structure 421 may include merely the first line layer 401.

The first dielectric layer in the first line layer 401 is used for isolation between the first lines, and the first dielectric layer may be a single layer or a multi-layer stacked structure, and the material of the first dielectric layer is one or more of silicon oxide, silicon nitride, silicon oxynitride, silicon oxycarbide, or silicon carbonitride. The first lines may also be a single-layer or a multi-layer line structure, and the material of the first lines is metal, in some implementations, it may be one or more of Al, Cu, W, Au, Ag, Pt, Ni, Ti, Ta, TiN, TaN, TaC, or WN.

The first bridge structure 421 is mounted on the silicon substrate 103, and the first welding bumps 401a being electrically connected with the silicon substrate 103 includes: the first bridge structure 421 is electrically connected with a part of the first redistribution layer 101 (or a part of the first wirings 105) in the silicon substrate 103; in some implementations, the first welding bumps 401a in the first line layer 401 in the first bridge structure 421 is welded together with a part of the first wirings 105 in the first redistribution layer 101 in the silicon substrate 103 through solder.

In one embodiment, the first bridge structure 421 located on the upper surface of the silicon substrate 103 outside the array of functional submodules 20, in addition to connecting the corresponding functional submodules 20, may also be connected to devices mounted on the lower surface of the silicon substrate 103 through lines in the silicon substrate 103.

In one embodiment, when the number of first bridge structures 421 mounted on the upper surface of the silicon substrate 103 at each edge of the functional submodules 20 is at least two, such as two or three, the at least two first bridge structures 421 are arranged along a direction parallel to the edge of the functional submodules 20.

In one embodiment, the first support layer 402 is a single layer or a multi-layer stacked structure. The material of the first support layer 402 is one or more of silicon, germanium silicon, silicon carbide, glass, resin, or PCB core board.

In one embodiment, the first bridge structure 421 is manufactured using an integrated manufacturing process to improve the manufacturing efficiency of the first bridge structure 421. In some implementations, the manufacturing process of the first bridge structure 421 may include: providing a support carrier board, the support carrier board is subsequently used to form a first support layer; forming an initial line layer on the upper surface of the support carrier board, the initial line layer includes a plurality of discrete first line layers 401; and forming a plurality of discrete first bridge structures 421 for the initial line layers and the support carrier board, and each first bridge structure 421 includes the first support layer 402 and the first line layer 401 located on the first support layer 402.

In one embodiment, referring again to FIGS. 1 and 3, it further includes: a second bridge structure 422 mounted on the upper surface of the silicon substrate 103 at the corner heads of the functional submodules 20, and the second bridge structure 422 is used to interconnect adjacent functional submodules 20 around the corner heads, and channels for connection (or interconnection) of adjacent functional submodules 20 are further increased through the second bridge structure 422 (also including the second bridge structure 422 in addition to wirings in the silicon substrate 103 and the first bridge structure 421), thereby further improving the band-width between adjacent functional submodules 20, so as to further improving the overall band-width of the wafer scale system-in-package structure.

In one embodiment, referring to FIG. 3, the second bridge structure 422 includes a second line layer 403 and a second support layer 404 located on the upper surface of the second line layer 403, and the second line layer 403 includes a second dielectric layer, second lines located in the second dielectric layer, and second welding bumps 403a protruding from the lower surface of the second dielectric layer and electrically connected with the second lines, and when the second bridge structure 422 is mounted on the upper surface of the silicon substrate, the second welding bumps 403a is electrically connected with a part of the first redistribution layer 101 in the silicon substrate 103, and the second bridge structure 422 together with a part of the first redistribution layer 101 in the silicon substrate interconnects adjacent functional submodules 20 around the corner head. Through the second bridge structure 422 of the aforementioned specific structure, channels for connection (or interconnection) of adjacent functional submodules 20 are further increased through the second bridge structure 422 (also including the second bridge structure 422, in addition to wirings in the silicon substrate 103 and the first bridge structure 421), thereby further improving the band-width between adjacent functional submodules 20, thus further improving the overall band-width of the wafer scale system-in-package structure. Meanwhile, the second support layer 404 provides physical support for the second line layer 403 (because the second line layer 403 is typically very thin and cannot be processed as a standalone device) and protects the second line layer 403 from failures such as breakage of line caused by warping; moreover, the large stresses existing at the corner heads and near the corner heads of adjacent functional submodules can be buffered and balanced through the second support layer 404, so that the warping in the wafer scale system-in-package structure caused by large stresses at the corner heads of the functional submodules 20 may be reduced.

The second dielectric layer in the second line layer 403 is used for isolation between the second lines, and the second dielectric layer may be a single layer or a multi-layer stacked structure, and the material of the second dielectric layer is one or more of silicon oxide, silicon nitride, silicon oxynitride, silicon oxycarbide, or silicon carbonitride. The second line may also be a single-layer or a multi-layer line structure, and the material of the second lines is metal, in some implementations, it may be one or more of Al, Cu, W, Au, Ag, Pt, Ni, Ti, Ta, TiN, TaN, TaC, or WN.

The second bridge structure 422 being mounted on the silicon substrate 103, and the second welding bumps 403a being electrically connected with the silicon substrate 103 includes: the second bridge structure 422 is electrically connected with a part of the first redistribution layer 101 (or a part of the first wirings 105) in the silicon substrate 103; in some implementations, the second welding bumps 403a in the second line layer 403 in the second bridge structure 422 are welded together with a part of the first wirings 105 in the first redistribution layer 101 in the silicon substrate 103 through solder.

In one embodiment, the second bridge structure 422 located on the upper surface of the silicon substrate 103 outside the array of functional submodules 20, in addition to connecting the corresponding functional submodules 20, may also be connected to devices mounted on the lower surface of the silicon substrate 103 through lines within the silicon substrate 103.

In one embodiment, the number of the first bridge structure 421 mounted on the surface of the silicon substrate 103 at each corner of the functional submodules 20 is one, and the first bridge structure 421 is used to interconnect the 2 or 4 functional submodules 20 around the corner head.

In one embodiment, the second bridge structure 422 is manufactured using an integrated manufacturing process to improve the manufacturing efficiency of the second bridge structure 422. In some implementations, the manufacturing process of the second bridge structure 422 may include: providing a support carrier board, the support carrier board is subsequently used to form a second support layer; forming an initial line layer on the upper surface of the support carrier board, and the initial line layer includes a plurality of discrete second line layers 403; etching or cutting the initial support carrier board and initial line layer to form a plurality of discrete second bridge structures 422, and each second bridge structures 422 includes the second support layer 404 and the second line layer 403 located on the second support layer 404; and removing the carrier board.

Referring again to FIG. 3, the second support layer 404 is a flexible structure, the rigidity of the second support layer 404 is less than the rigidity of the first molding layer 111, such that the larger stresses that existing at the corner heads and near the corner heads of adjacent functional submodules 20 are effectively buffered and balanced by the second support layer 404, thereby reducing warping in wafer scale system-in-package structures caused by high stresses at the corner heads of functional submodules 20.

In one embodiment, referring to FIGS. 3 and 4, the second support layer 404 of the flexible structure includes a first buffer layer 406, a core layer 408 located on the surface of the first buffer layer 406, and a second buffer layer 407 located on the surface of the core layer 408, the core layer 408 has in it blind vias 409, and a part of the lower surface of the heat dissipation cover 601 is mounted on the surface of the second buffer layer 407 through an adhesive. There are cavities in the blind vias 409, or the blind vias 409 are fully filled with filler material 411 (referring to FIG. 4), and when the heat dissipation cover 601 is mounted subsequently (referring to FIG. 6), a part of the lower surface of the heat dissipation cover 601 is mounted on the surface of the second buffer layer 407 in the second support layer 404. In addition to the fact that large stresses existing at the corner heads and near the corner heads of adjacent functional submodules 20 can be effectively buffered and balanced by the second support layer 404, the second support layer 404 also provides support and cushioning pads for the back surface of the heat dissipation cover 601.

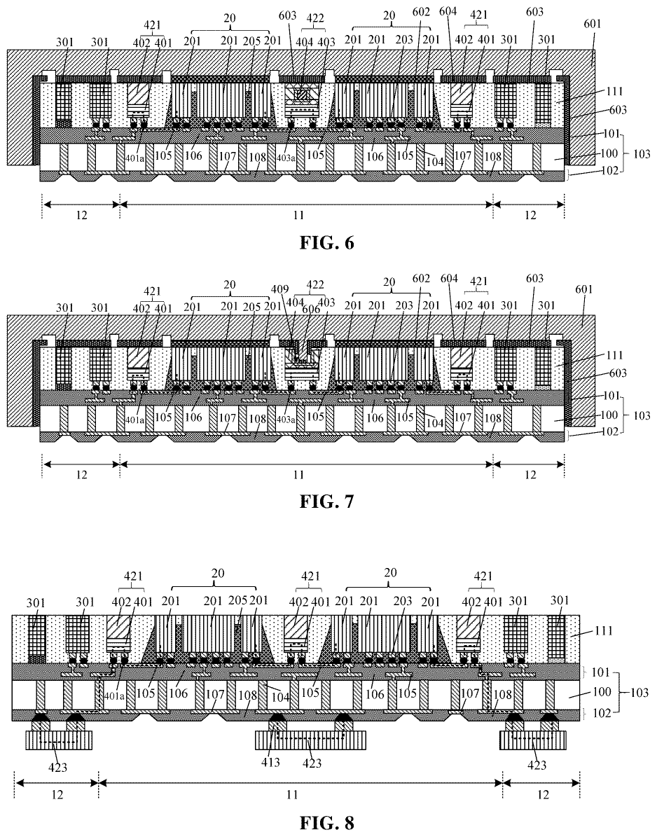

In another embodiment, referring to FIG. 5, the second support layer 404 of the flexible structure includes a first buffer layer 406, a core layer 408 located on the upper surface of the first buffer layer 406, and a second buffer layer 407 located on the upper surface of the core layer 408, the second buffer layer 407 and the core layer 408 have in them blind vias 409, the blind vias 409 run through the second buffer layer 407 and the core layer 408; on the one hand, the rigidity of the second support layer 404 of this structure is small, so that the larger stresses existing at the corner heads and near the corner heads of adjacent functional submodules 20 are effectively buffered and balanced; on the other hand, when subsequently mounting the heat dissipation cover 601 (referring to FIG. 7), the second support layer 404 provides support and cushioning pads for the lower surface of the heat dissipation cover 601, and provides a mounting interface for the anchoring protrusions 606 of the lower surface of the heat dissipation cover 601; meanwhile, when mounting the heat dissipation cover 601, the anchoring protrusions 606 of the lower surface of the heat dissipation cover 601 are correspondingly mounted in the corresponding blind vias 409, i.e., the blind vias 409 also provide a limiting space for the anchoring protrusions 606 of the lower surface of the heat dissipation cover 601, which improves the alignment accuracy when mounting the heat dissipation cover 601, and defines the mounting accuracy of the heat dissipation cover 601 during the mounting process and the adhering process of the heat dissipation cover 601, and when the anchoring protrusions 606 of the lower surface of the heat dissipation cover 601 are correspondingly mounted in the corresponding blind vias 409, the anchoring protrusions 606 are locked in the blind vias, which improves the firmness of mounting of the heat dissipation cover 601.

In one embodiment, the first buffer layer 406 and second buffer layer 407 are used for stress buffering between the upper surface and the lower surface of the second support layer 404, on the one hand, and other structures, on the other hand. The materials of the first buffer layer 406 and the second buffer layer 407 are organic or inorganic buffer materials, and the material of the core layer 408 is PCB or substrate material.

In one embodiment, referring again to FIG. 5, the blind vias 409 may be formed through laser drilling or mechanical drilling, and according to the depth of the blind vias 409 being different, the type of filler material 411 fully filled in the blind vias 409 may be different. When the depth of the blind vias 409 is less than 200 micrometers, the filler material 411 in the blind vias 409 is copper; when the depth of the blind vias is greater than 200 micrometers and less than 500 micrometers, the filler material 411 in the blind vias 409 is ink or composite material; when the depth of the blind vias is greater than 500 micrometers, the filler material 411 in the blind vias 409 is a via-filling composite material.

In one embodiment, referring to FIG. 4 or FIG. 5, the sidewall surfaces of the blind vias 409 further have a metal layer 410. In one embodiment, referring to FIG. 5, when the blind vias 409 are filled with a filler material 411, in addition to the fact that the sidewall surfaces of the blind vias 409 have a metal layer 410, there are also metal layers above and below the filler material 411.

Referring again to FIGS. 1-3, it further includes: a first molding layer 111 located on the upper surface of the silicon substrate 103 and covering the functional submodules 20, the first bridge structure 421, the second bridge structure 422, and the edge dummy devices 301, and the first molding layer 111 exposes the upper surfaces of the functional submodules 20, the first bridge structure 421, and the second bridge structure 422. (It should be noted that after the active surface of the semiconductor chip 201 is mounted facing downward on the upper surface of the silicon substrate 103, the surface where the back surface of the semiconductor chip 201 is located is the upper surface of the functional submodules 20, or the surface of the semiconductor chip 201 far away from the silicon substrate 103 is the upper surface of the functional submodules 20; after the edge dummy devices 301 are mounted on the upper surface of the silicon substrate 103, the surfaces of the edge dummy devices 301 far away from the silicon substrate 103 are the upper surfaces of the edge dummy devices 301; after the first bridge structure 421 and the second bridge structure 422 are mounted on the upper surface of the silicon substrate 103, the surfaces of the first bridge structure 421 and the second bridge structure 422 far away from the silicon substrate 103 are the upper surfaces of the first bridge structure 421 and second bridge structure 422).

The material of the first molding layer 111 may be filler-containing epoxy resin, polyimide resin, benzocyclobutene resin, or polybenzoxazole resin; alternatively, it may also be filler-containing polybutylene terephthalate, polycarbonate, polyethylene terephthalate, polyethylene, polypropylene, polyolefin, polyurethane, polyolefin, polyether sulfone, polyamide, polyurethane, ethylene-vinyl acetate copolymer, or polyvinyl alcohol. In some embodiments, the filler may be an inorganic filler or an organic filler. In some embodiments, the process for forming the first molding layer 111 includes compression molding or transfer molding.

In one embodiment, referring to FIG. 6 or FIG. 7, the package structure further includes: a heat dissipation cover 601 mounted on the upper surfaces of the first molding layer 111, the functional submodules 20, the first bridge structure 421, the second bridge structure 422, and on the side surfaces of the first molding layer 111 and the silicon substrate 103.

The heat dissipation cover 601 is used to dissipate heat from the package structure. The heat dissipation cover 601 is in the shape of a “cover” shape, and the heat dissipation cover 601 may include a cover top and a cover rim protruding from the lower surface of the edge of the cover top. The lower surface of the cover top of the heat dissipation cover 601 is mounted on the upper surfaces of the first molding layer 111, the functional submodules 20, the first bridge structure 421, and the second bridge structure 422, the inner wall surface of the cover rim of the heat dissipation cover 601 is mounted on the side surfaces of the first molding layer 111 and the silicon substrate 103. In some implementations, referring to FIG. 6, the lower surface of the heat dissipation cover 601 does not have protruding anchoring protrusions, and a part of the lower surface of the cover top of the heat dissipation cover 601 is mounted on the upper surface of the first molding layer 111 and the second buffer layer in the second support layer 404 of the second bridge structure 422 through adhesive 603, and a part of the lower surface of the cover top of the heat dissipation cover 601 is mounted on the upper surface of the first support layer 402 of the first bridge structure 421 through adhesive or heat dissipation cover 604, and a part of the lower surface of the cover top of the heat dissipation cover 601 is mounted on the upper surface of the functional submodules 20 through heat dissipation adhesive 602, and the inner wall surface of the cover rim of the heat dissipation cover 601 is mounted on the outer side surface of the first molding layer 111 and the silicon substrate 103 through adhesive 603.

In another specific embodiment, referring to FIG. 7, the lower surface of the cover top of the heat dissipation cover 601 has a plurality of downward protruding anchoring protrusions 606, and the anchoring protrusions 606 are mounted in corresponding blind vias 409 through adhesive 603, and the lower surface of the horizontal cover top of the heat dissipation cover 604 is mounted on the upper surfaces of the first molding layer 111, the functional submodules 20, and the first bridge structure 421, and the inner wall surface of the cover rim of the heat dissipation cover 601 is mounted on the outer surface of the first molding layer 111 and the silicon substrate 103.

In one embodiment, the material of the heat dissipation cover 601 is a material with high thermal conductivity, it includes metals (e.g., copper, aluminum, gold, nickel, steel, or stainless steel) or carbon-containing materials (e.g., graphite, graphene, or carbon nanotubes).

In one embodiment, referring to FIG. 8, the package structure further includes: a bridge chip 423 mounted on the lower surface of the silicon substrate 103, and the bridge chip 423 is electrically connected with a part of the second redistribution layer 102, and the bridge chip 423 is used to interconnect adjacent functional submodules 20 above the bridge chip 423 through a part of the second redistribution layer 102, the through-silicon-vias 104, and a part of the first redistribution layer 101, thereby achieving diversity in interconnection between adjacent functional submodules 20, which further improves the band-width between adjacent functional submodules 20, thus improving the overall band-width of the wafer scale system-in-package structure.

In one embodiment, the bridge chip 423 includes third lines and third welding bumps 413 connected with the third lines. The electrical connection of the bridge chip 423 with a part of the second redistribution layer 102 includes: the welding bumps 413 on the bridge chip 423 are welded together with a part of the second wirings 107 in the second redistribution layer 102 of the silicon substrate 103.

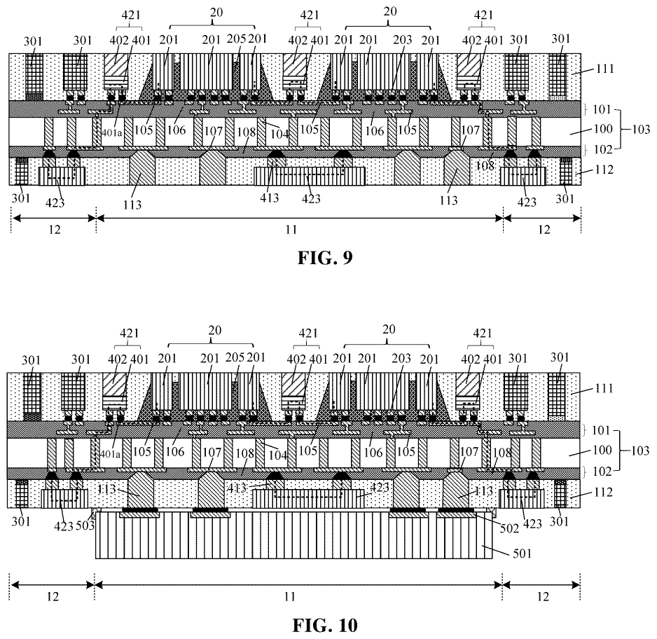

In one embodiment, referring to FIG. 9, the package structure further includes: metal bumps 113 protruding from the lower surface of the silicon substrate 103 and connected with a part of the second redistribution layer 102, and the lower surfaces of the metal bumps 113 are not lower than the lower surface of the bridge chip 423, and in some implementations, the lower surface of the metal bumps 113 may be flush with the lower surface of the bridge chip 423 or higher than the lower surface of the bridge chip 423. The metal bumps 113 are used for electrical connection between the package structure and other devices, and in some implementations, one end of the metal bumps 113 may be electrically connected with a part of the second wirings 107 in the second redistribution layer 102, the material of the metal bumps 113 is metal, and it may be one or more of Al, Cu, W, Au, Ag, Pt, Ni, Ti, Ta, TiN, TaN, TaC, or WN; and a second molding layer 112 located on the lower surface of the silicon substrate 103 and covering the bridge chip 423 and the metal bumps 113, and the second molding layer 112 exposes the lower surfaces of the metal bumps 113 and the bridge chip 423.

In one embodiment, referring again to FIG. 9, it further includes: edge dummy devices 301 of different sizes mounted on the lower surface of the edge area of the silicon substrate 103 outside the array of functional submodules 20, and the second molding layer 112 also covers the edge dummy devices 301 and exposes the lower surfaces of the edge dummy devices 301. The edge dummy devices 301 of different sizes mounted on the lower surface of the edge area of the silicon substrate 103 outside the array of functional submodules 20 can further balance the Si/EMC ratio to further balance warping.

The second molding layer 112 is used to protect the lines and devices on the lower surface of the silicon substrate 103. The properties of the second molding layer 112 may be the same as or different from the properties of the first molding layer 111. In one embodiment, the properties of the second molding layer 112 are different from the properties of the first molding layer 111, and in some implementations, the thickness of the second molding layer 112 is less than the thickness of the first molding layer 111, and the thermal expansion coefficient and/or Young's modulus of the second molding layer 112 is equal to or higher than the thermal expansion coefficient and/or Young's modulus of the first molding layer 111, through the second molding layer 112 of this specific property (including specific thickness and specific thermal expansion coefficient and/or Young's modulus), the difference in thermal expansion coefficient and/or Young's modulus of the unbalanced structure and material on the upper surface and the lower surface of the silicon substrate 103 can be balanced or reduced, therefore, warping issues in the wafer scale system-in-package structure caused by significant differences in thermal expansion coefficients and/or Young's modulus of the unbalanced structure and material of the upper surface and the lower surface of the silicon substrate 103 can be prevented, so that warping of the system package structure for wafer scale ultra large core modules at room temperature or high temperatures is effectively controlled.

In one embodiment, the fact that the thermal expansion coefficient and/or Young's modulus of the second molding layer 112 is equal to or higher than the thermal expansion coefficient and/or Young's modulus of the first molding layer 111 can be divided into a variety of cases, wherein the first case is: the thermal expansion coefficient of the second molding layer 112 is equal to or higher than the thermal expansion coefficient of the first molding layer 111; the second case is: the Young's modulus of the second molding layer 112 is equal to or higher than the Young's modulus of the first molding layer 111; the third scenario is: both the thermal expansion coefficient and Young's modulus of the second molding layer 112 are equal to or higher than the thermal expansion coefficient and Young's modulus of the first molding layer 111. It should be noted that “equal to” in the present disclosure can be divided into two cases, one case is that the two are completely equal in numerical value, for example, the value of the thermal expansion coefficient of the second molding layer 112 is completely equal to the value of the thermal expansion coefficient of the first molding layer 111; another case is that, within a numerical deviation within ±20%, the two are also considered to be “equal”, for example, when the value of the thermal expansion coefficient of the second molding layer 112 is greater than or less than the value of the thermal expansion coefficient of the first molding layer 111 by a difference within ±20%, they are considered to be “equal,” for another example, when the value of the curing shrinkage rate of the second molding layer 112 is greater than or less than the value of the curing shrinkage rate of the first molding layer 111 by a difference within ±20%, they are considered to be “equal.” In the present disclosure, “higher than” indicates a difference between the two is greater than 20%, for example, the thermal expansion coefficient of the second molding layer 112 is higher than the thermal expansion coefficient of the first molding layer 111 indicates: the value of the thermal expansion coefficient of the second molding layer 112 is greater than the value of the thermal expansion coefficient of the first molding layer 111 by more than 20%, for another example, the curing shrinkage rate of the second molding layer 112 is also higher than the curing shrinkage rate of the first molding layer 111 indicates: the value of the curing shrinkage rate of the second molding layer 112 is greater than the value of the curing shrinkage rate of the first molding layer 111 by more than 20%.

In one embodiment, referring to FIG. 10, the package structure further includes: a power supply module 501 mounted on the lower surface of the second molding layer 112 and electrically connected with the metal bumps 113, and the power supply module 501 is used to supply power to at least two adjacent functional submodules 20 on the upper surface of the silicon substrate 103.

The power supply module 501 can convert an external input voltage into a voltage of a specific magnitude and specific power for supplying to the corresponding functional submodules 20.

In one embodiment, the number of power supply modules 501 can be one or more. When the number of power supply modules 501 is one, one power supply module 501 supplies power to all functional submodules 20 on the upper surface of the silicon substrate 103. When the number of power supply modules 501 is multiple, each power supply module 501 supplies power to a plurality of (in some implementations, they may be two-four) adjacent functional submodules 20 on the upper surface of the silicon substrate 103.

In one embodiment, the power supply module 501 includes a PCB substrate, connection lines located in the PCB substrate, and a plurality of solder pads 502 located on the upper surface of the PCB substrate, the solder pads 502 are electrically connected with the connection lines, and a power control chip mounted on the lower surface of the PCB or embedded in the PCB substrate, and the power control chip is electrically connected with the connection lines, and the solder pads 502 are welded together with corresponding metal bumps 113 on the lower surface of the silicon substrate 103 through solder.

In one embodiment, referring again to FIG. 10, it further includes: bonding material 503 that secures the four corner heads of the power supply module 501 with the corresponding lower surface of the second molding layer 112. A plurality of corners of the power supply module 501 are further secured with the second molding layer 112 through bonding material 503 to improve the firmness of the mounting of the large-sized power supply module 501.

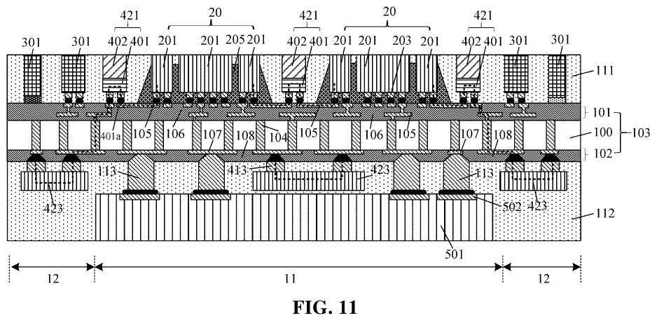

In another embodiment, the structure of the second molding layer 112 in the package structure differs from that in the aforementioned embodiments, referring to FIG. 11 for details, and the second molding layer 112 covers the bridge chip 423, the metal bumps 113, the power supply module 501, and the edge dummy devices (not shown in the figures) located on the lower surface of the silicon substrate 103, the lower surfaces of the power supply module 501 and the edge dummy devices are exposed by the second molding layer 112.

Another embodiment of the present disclosure further provides a method for forming a wafer scale system-in-package structure, and the formation method is described below in conjunction with the accompanying drawings (it should be noted that the same or similar parts of the present embodiment (method for forming a wafer scale system-in-package structure) and the aforementioned embodiment (wafer scale system-in-package structure) are not repeated in the present embodiment, for the details, reference may be made to the definitions or descriptions of the corresponding parts in the aforementioned embodiment).

Referring to FIGS. 1-3, a silicon substrate 103 is provided, the silicon substrate 103 including opposed upper surface and lower surface; a plurality of function submodules 20 arranged in an array are mounted on the upper surface of the silicon substrate 103, and each function submodule 20 includes four corner heads and edges located between adjacent corner heads, the function submodules 20 being electrically connected with the silicon substrate 103; a first bridge structure 421 is mounted on the upper surface of the silicon substrate 103 at the edges of the functional submodules 20, and the first bridge structure 421 is used to interconnect adjacent functional submodules 20; a second bridge structure 422 is mounted on the upper surface of the silicon substrate 103 at the corner heads of the functional submodules 20, and the second bridge structure 422 is used to interconnect adjacent functional submodules 20 around the corner heads; and formed on the upper surface of the silicon substrate 103 is a first molding layer 111 covering the functional submodules 20, the first bridge structure 421, and the second bridge structure 422, and the first molding layer 111 exposes the upper surfaces of the functional submodules 20, the first bridge structure 421, and the second bridge structure 422.

In one embodiment, it further includes: edge dummy devices 301 of different sizes are mounted on the upper surface of the edge area of the silicon substrate 103 outside the array of functional submodules 20. The first molding layer 111 further covers the edge dummy devices 301 and exposes the upper surfaces of the edge dummy devices 301; the edge dummy devices 301 are one or more of passive devices, heat dissipation discrete components, or dummy chips.

In one embodiment, the first bridge structure 421 includes a first line layer 401 and a first support layer 402 located on the upper surface of the first line layer 401, and the first line layer 401 includes a first dielectric layer, first lines located in the first dielectric layer, and first welding bumps 401a protruding from the lower surface of the first dielectric layer and electrically connected with the first lines, and the first welding bumps 401a are welded together with the silicon substrate 103.

In one embodiment, the first support layer 402 is a single-layer or a multi-layer stacked structure. The material of the first support layer is one or more of silicon, germanium silicon, silicon carbide, glass, resin, or PCB core board.

In one embodiment, the number of first bridge structures 421 mounted on the upper surface of the silicon substrate 103 of each edge of the functional submodules 20 is at least two, the at least two first bridge structures 421 are arranged along a direction parallel to the edge of the functional submodules 20.

In one embodiment, the second bridge structure 422 includes a second line layer 403 and a second support layer 404 located on the upper surface of the second line layer 403, and the second line layer 403 includes a second dielectric layer, second lines located in the second dielectric layer, and second welding bumps 403a protruding from the lower surface of the second dielectric layer and electrically connected with the second lines, and the second welding bumps 403a are welded together with the silicon substrate 103.

In one embodiment, the second support layer 404 is a flexible structure, and the rigidity of the second support layer 404 is less than the rigidity of the first molding layer. In some implementations, referring to FIGS. 5 and 7, the second support layer 404 of the flexible structure includes a first buffer layer 406, a core layer 408 located on the upper surface of the first buffer layer 406, and a second buffer layer 407 located on the upper surface of the core layer 408, the second buffer layer 407 and the core layer 408 have in them blind vias 409, the blind vias 409 run through the second buffer layer 407 and the core layer 408, and the blind vias 409 are exposed by the first molding layer 111; it further includes: a heat dissipation cover 601, the heat dissipation cover 601 includes a horizontal cover top, a cover rim protruding from the lower surface of the edge of the horizontal cover top, and a plurality of downward anchoring protrusions 606 protruding from the lower surface of the horizontal cover top, and the lower surface of the horizontal cover top of the heat dissipation cover 601 is mounted on the upper surfaces of the first molding layer 111, the functional submodules 20, and the first bridge structure 421, and the anchoring protrusions 606 are mounted in corresponding blind vias 409 through adhesive, and the inner wall surface of the cover rim of the heat dissipation cover 604 is mounted on the outer surface of the first molding layer 111 and the silicon substrate 103.

In some implementations, referring to FIGS. 4 and 6, the second support layer 404 of the flexible structure includes a first buffer layer 406, a core layer 408 located on the surface of the first buffer layer 406, and a second buffer layer 407 located on the surface of the core layer 408, and the core layer 408 has in it blind vias 409, and there are cavities in the blind vias 409, or filler material fully fills the blind vias 409, and the second buffer layer 407 seals the openings of the blind vias 409, and the first molding layer 111 exposes the upper surface of the second buffer layer 407; and it further includes: mounting a heat dissipation cover 601, and the heat dissipation cover 601 includes a horizontal cover top and a cover rim protruding from the lower surface of the edge of the horizontal cover top, and the lower surface of the horizontal cover top of the heat dissipation cover 601 is mounted on the upper surface of the first molding layer 111, the functional submodules 20, the first bridge structure 421, and the second buffer layer of the second bridge structure 422, and the inner wall surface of the cover rim of the heat dissipation cover 601 is mounted on the outer surface of the first molding layer and the silicon substrate.

In one embodiment, the silicon substrate 103 includes a silicon wafer body 100, a first redistribution layer 101 located on the upper surface of the silicon wafer body 100, and a second redistribution layer 102 located on the lower surface of the silicon wafer body 100, and the silicon wafer body 100 has in it through-silicon-vias 104, the through-silicon-vias 104 electrically connect the first redistribution layer 101 and the second redistribution layer 102; the functional submodules 20, the first bridge structure 421, and the second bridge structure 422 are electrically connected with different parts of the first redistribution layer 101, respectively, and the adjacent functional submodules 20 are interconnected through the first bridge structure 421 and/or the second bridge structure 422 and through a part of the first redistribution layer 101 in the silicon substrate 103.

In one embodiment, referring to FIG. 8, it further includes: a bridge chip 423 is mounted on the lower surface of the silicon substrate 103, and the bridge chip 423 is electrically connected with a part of the second redistribution layer 102, and the bridge chip 423 interconnects the adjacent functional submodules 20 above the bridge chip 423 through a part of the second redistribution layer 102, the through-silicon-vias 104, and a part of the first redistribution layer 101.

In one embodiment, referring to FIG. 9, it further includes: formed on the lower surface of the silicon substrate 103 is metal bumps 113 protruding and connected with a part of the second redistribution layer 102, and the lower surface of the metal bumps 113 are not lower than the lower surface of the bridge chip 423; edge dummy devices 301 of different sizes are mounted on the lower surface of the edge area of the silicon substrate 103 outside the array of functional submodules; formed on the lower surface of the silicon substrate 103 is a second molding layer 112 covering the bridge chip 423, the edge dummy devices 301, and the metal bumps 113, and the second molding layer 112 exposes the lower surfaces of the bridge chip 423, the edge dummy devices 301, and the metal bumps 113. In one embodiment, referring to FIG. 10, a power supply module 501 is mounted on the lower surface of the second molding layer 112 and electrically connected with the metal bumps 113, and the power supply module 501 is used to supply power to at least two adjacent functional submodules 20 on the upper surface of the silicon substrate 103.

In one embodiment, referring again to FIG. 10, a bonding material 503 is formed that secures a plurality of top corners of the power supply module 501 with a part of the upper surface of the second molding layer 112.

In one embodiment, referring to FIG. 11, formed on the lower surface of the silicon substrate 103 are metal bumps 113 protruding and connected with a part of the second redistribution layer 102, and the lower surface of the metal bumps 113 are not lower than the lower surface of the bridge chip 423; a power supply module 501 is mounted on the lower surface of the metal bumps 113; edge dummy devices of different sizes are mounted on the lower surface of the edge area of the silicon substrate 103 outside the array of functional submodules 20 (not shown in the figures); and formed on the lower surface of the silicon substrate 103 is a second molding layer 112 covering the bridge chip 423, the metal bumps 113, the power supply module 501, and the edge dummy devices, and the second molding layer 112 exposes the lower surfaces of the power supply module 501 and the edge dummy devices.

Although the present disclosure has been disclosed above with some embodiments, it is not intended to limit the present disclosure. Any person skilled in the art may make possible changes and modifications to the technical solutions disclosed herein without departing from the spirit and scope of the present disclosure, therefore, any simple modifications, equivalent changes, and refinements made to the above embodiments based on the technical essence of the present disclosure that do not depart from the content of the technical solutions of the present disclosure, shall fall within the scope of protection of the technical solutions of the present disclosure.

What is claimed is:

1. A wafer scale system-in-package structure, comprising:
a silicon substrate comprising an upper surface and a lower surface opposite to the upper surface;
a plurality of functional submodules mounted on the upper surface of the silicon substrate and arranged in an array, wherein each of the plurality of functional submodules comprises four corners and four edges each between adjacent corners, and the functional submodules are electrically connected to the silicon substrate;
a first bridge structure mounted on the upper surface of the silicon substrate at the edges of the functional submodules, and the first bridge structure is configured to interconnect adjacent functional submodules;
a second bridge structure mounted on the upper surface of the silicon substrate at the corners of the functional submodules, and the second bridge structure is configured to interconnect adjacent functional submodules around the corners; and
a first molding layer located on the upper surface of the silicon substrate and covering the functional submodules, the first bridge structure, and the second bridge structure, and the first molding layer exposes upper surfaces of the functional submodules, the first bridge structure, and the second bridge structure.

2. The wafer scale system-in-package structure according to claim 1, wherein:
structures of the plurality of functional submodules are the same, and the functional submodules comprise at least two semiconductor chips, and the at least two semiconductor chips are mounted on the upper surface of the silicon substrate in a flip-chip manner; and
each of the plurality of functional submodules further comprises an underfill layer filled between a lower surface of one of the at least two semiconductor chips and the upper surface of the silicon substrate and covering a side surface of the one of the at least two semiconductor chips.

3. The wafer scale system-in-package structure according to claim 1, further comprising:
edge dummy devices of different sizes mounted on the upper surface of an edge area of the silicon substrate outside the array of the plurality of functional submodules,
wherein the first molding layer further covers the edge dummy devices and exposes upper surfaces of the edge dummy devices, and each of the edge dummy devices comprises one or more of: a passive device, a heat dissipation device, or a dummy chip.

4. The wafer scale system-in-package structure according to claim 1, wherein:
the first bridge structure comprises a first line layer and a first support layer located on an upper surface of the first line layer;
the first line layer comprises: a first dielectric layer; first lines in the first dielectric layer; and first welding bumps protruding from a lower surface of the first dielectric layer and electrically connected to the first lines; and
when the first bridge structure is mounted on the upper surface of the silicon substrate, the first welding bumps are electrically connected to the silicon substrate, and the first bridge structure and the silicon substrate interconnect adjacent functional submodules.

5. The wafer scale system-in-package structure according to claim 4, wherein:
the first support layer of the first bridge structure is a single layer or a multi-layer stacked structure; and
a material of the first support layer of the first bridge structure comprises one or more of: silicon, germanium silicon, silicon carbide, glass, resin, or Printed Circuit Board (PCB) core board.

6. The wafer scale system-in-package structure according to claim 4, wherein a number of the first bridge structures mounted on the upper surface of the silicon substrate at each edge of the plurality of functional submodules is at least two, and the plurality of first bridge structures are arranged in a direction parallel to one of the edges of the plurality of functional submodules.

7. The wafer scale system-in-package structure according to claim 1, wherein:
the second bridge structure comprises: a second line layer; and a second support layer on the upper surface of the second line layer;
the second line layer comprises: a second dielectric layer; second lines in the second dielectric layer; and second welding bumps protruding from a lower surface of the second dielectric layer and electrically connected to the second lines; and
when the second bridge structure is mounted on the upper surface of the silicon substrate, the second welding bumps are electrically connected to the silicon substrate, and the second bridge structure and the silicon substrate interconnect the adjacent functional submodules around the corners.

8. The wafer scale system-in-package structure according to claim 7, wherein the second support layer is a flexible structure, and a rigidity of the second support layer is less than that of the first molding layer.

9. The wafer scale system-in-package structure according to claim 8, wherein:
the second support layer of the flexible structure comprises: a first buffer layer; a core layer on an upper surface of the first buffer layer; and a second buffer layer located on an upper surface of the core layer; and
the second buffer layer and the core layer comprise blind vias extending through the second buffer layer and the core layer, the first molding layer exposes the blind vias, and sidewalls of the blind vias comprise a metal layer.

10. The wafer scale system-in-package structure according to claim 9, further comprising:
a heat dissipation cover comprising:
a horizontal cover top;
a cover rim protruding from a lower surface of an edge of the horizontal cover top; and
a plurality of anchoring protrusions protruding from the lower surface of the horizontal cover top,
wherein the lower surface of the horizontal cover top is mounted on upper surfaces of the first molding layer, the functional submodules, the first bridge structure, and the second bridge structure, and
each of the plurality of anchoring protrusions is mounted in corresponding blind vias through adhesive, and an inner wall of the cover rim is mounted on an outer surface of the first molding layer and the silicon substrate.

11. The wafer scale system-in-package structure according to claim 8, wherein the second support layer of the flexible structure comprises:
a first buffer layer;
a core layer on the upper surface of the first buffer layer; and
a second buffer layer on the upper surface of the core layer,
wherein:
the core layer comprises blind vias, and the blind vias comprise cavities or are fully filled with filler material;
the second buffer layer seals openings of the blind vias;
the first molding layer exposes an upper surface of the second buffer layer; and
sidewalls of the blind vias comprise a metal layer.

12. The wafer scale system-in-package structure according to claim 11, further comprising:
a heat dissipation cover comprising:
a horizontal cover top; and
a cover rim protruding from a lower surface of an edge of the horizontal cover top,
wherein the lower surface of the horizontal cover top of the heat dissipation cover is mounted on upper surfaces of the first molding layer, the functional submodules, the first bridge structure, and the second buffer layer of the second bridge structure, and
an inner wall of the cover rim is mounted on an outer surface of the first molding layer and the silicon substrate.

13. The wafer scale system-in-package structure according to claim 1, wherein the silicon substrate comprises:
a silicon wafer body;
a first redistribution layer on an upper surface of the silicon wafer body; and
a second redistribution layer on the lower surface of the silicon wafer body, wherein the silicon wafer body comprises through-silicon-vias, and the through-silicon-vias electrically connect the first redistribution layer and the second redistribution layer.

14. The wafer scale system-in-package structure according to claim 13, further comprising:
a bridge chip mounted on the lower surface of the silicon substrate and electrically connected to a part of the second redistribution layer,
wherein the bridge chip interconnects the adjacent functional submodules above the bridge chip through the part of the second redistribution layer, the through-silicon-vias, and a part of the first redistribution layer.

15. The wafer scale system-in-package structure according to claim 14, further comprising:
metal bumps protruding from the lower surface of the silicon substrate and connected to the part of the second redistribution layer, wherein lower surfaces of the metal bumps are not lower than a lower surface of the bridge chip;
edge dummy devices of different sizes mounted on the lower surface of an edge area of the silicon substrate outside the array of the plurality of functional submodules;
a second molding layer located on the lower surface of the silicon substrate and covering the bridge chip, the metal bumps, and the edge dummy devices, wherein the second molding layer exposes lower surfaces of the bridge chip, the metal bumps, and the edge dummy devices;
a power supply module mounted on a lower surface of the second molding layer and electrically connected to the metal bumps, and the power supply module supplies power to at least two adjacent functional submodules on the upper surface of the silicon substrate; and
a bonding material configured to secure four corners of the power supply module with the lower surface of the second molding layer.

16. The wafer scale system-in-package structure according to claim 14, further comprising:
metal bumps protruding from the lower surface of the silicon substrate and connected to the part of the second redistribution layer, wherein lower surfaces of the metal bumps are not lower than a lower surface of the bridge chip;
a power supply module mounted on the lower surfaces of the metal bumps;
edge dummy devices of different sizes mounted on the lower surface of an edge area of the silicon substrate outside the array of the plurality of functional submodules; and
a second molding layer located on the lower surface of the silicon substrate and covering the bridge chip, the metal bumps, the power supply module, and the edge dummy devices, wherein the second molding layer exposes lower surfaces of the power supply module and the edge dummy devices.

17. A method for forming a wafer scale system-in-package structure, comprising:
providing a silicon substrate, the silicon substrate comprising an upper surface and a lower surface opposite to the upper surface;
mounting, on the upper surface of the silicon substrate, a plurality of functional submodules arranged in an array, wherein each of the plurality of functional submodules comprises four corners and four edges each between adjacent corners, and the functional submodules are electrically connected to the silicon substrate;
mounting a first bridge structure on the upper surface of the silicon substrate at the edges of the functional submodules, wherein the first bridge structure is configured to interconnect adjacent functional submodules;
mounting a second bridge structure on the upper surface of the silicon substrate at the corners of the functional submodules, wherein the second bridge structure is configured to interconnect adjacent functional submodules around the corners; and
forming, on the upper surface of the silicon substrate, a first molding layer covering the functional submodules, the first bridge structure, and the second bridge structure, wherein the first molding layer exposes upper surfaces of the functional submodules, the first bridge structure, and the second bridge structure.

18. The method for forming a wafer scale system-in-package structure according to claim 17, further comprising:
mounting edge dummy devices of different sizes on the upper surface of an edge area of the silicon substrate outside the array of the plurality of functional submodules,
wherein the first molding layer covers the edge dummy devices and exposes upper surfaces of the edge dummy devices, and each of the edge dummy devices comprises one or more of: a passive device, a heat dissipation device, or a dummy chip.

19. The method for forming a wafer scale system-in-package structure according to claim 17, wherein:
the first bridge structure comprises: a first line layer; and a first support layer on an upper surface of the first line layer;
the first line layer comprises: a first dielectric layer; first lines in the first dielectric layer; and first welding bumps protruding from a lower surface of the first dielectric layer and electrically connected to the first lines; and
when the first bridge structure is mounted on the upper surface of the silicon substrate, the first welding bumps are electrically connected to the silicon substrate.

20. The method for forming a wafer scale system-in-package structure according to claim 17, wherein:
the silicon substrate comprises: a silicon wafer body; a first redistribution layer on an upper surface of the silicon wafer body; and a second redistribution layer on the lower surface of the silicon wafer body, wherein the silicon wafer body comprises through-silicon-vias, and the through-silicon-vias electrically connect the first redistribution layer and the second redistribution layer;
the functional submodules, the first bridge structure, and the second bridge structure are electrically connected to different parts of the first redistribution layer, respectively; and
the adjacent functional submodules are interconnected through the first bridge structure or the second bridge structure and through a part of the first redistribution layer in the silicon substrate.
